(19) United States
(12) Patent Application Publication
(10) Pub. No.: US 2009/0166195 A1
(43) Pub. Date: Jul. 2, 2009

(54) SPUTTERING APPARATUS

(75) Inventors: Yukihiro Kobayashi, Odawara-shi (JP); Koichi Yoshizuka, Hachioji-shi (JP); Toshiyuki Ota, Tokyo (JP)

Correspondence Address: FITZPATRICK CELLA HARPER & SCINTO, 30 ROCKEFELLER PLAZA, NEW YORK, NY, 10112, US

(73) Assignee: CANON ANELVA CORPORATION, Kawasaki-shi (JP)

(21) Appl. No.: 12/338,141

(22) Filed: Dec. 18, 2008

(30) Foreign Application Priority Data
Dec. 27, 2007 (JP) 2007-337370(PAT.)

(51) Int. Cl. C23C 14/34

(52) U.S. Cl. 204/298.11

(57) ABSTRACT

A sputtering apparatus to form a film on a substrate includes an electrode arranged in a vacuum chamber and having a placing surface to place a target on it, a stationary portion provided on the peripheral portion of the placing surface, a shutter mechanism to shield in the vacuum chamber the target placed on the placing surface, and a moving mechanism which sets in the vacuum chamber the shutter mechanism at a predetermined position. Of the stationary portion and the movable portion of the shutter mechanism, one is provided with a recess and the other one is provided with a projection. When the moving mechanism sets the shutter mechanism at a position close to the stationary portion, the projection is inserted in the recess.

### BACKGROUND OF THE INVENTION

1. Field of the Invention

The present invention relates to a sputtering apparatus and, more particularly, to a sputtering apparatus having a shutter mechanism suitable to prevent scattering of sputtering particles from a target arranged in a vacuum chamber which processes a substrate, or outflow of sputtering particles from another target.

2. Description of the Related Art

Among sputtering apparatuses, one is known in which a plurality of targets made of different target materials are provided in a vacuum chamber which processes a substrate by, for example, film formation. In this sputtering apparatus, the target is selected in accordance with the type of the film to be formed on the substrate, and the selected target is sputtered. In this manner, a desired multilayer film is formed on the substrate set in the vacuum chamber.

Each target is set on a placing surface provided to a corresponding electrode to place a target on it. Accordingly, electrodes are individually provided behind the respective targets. Power is supplied to each electrode to cause electric discharge on that surface of the target which is on the processing space side. A sputtering phenomenon is caused on the surface of the corresponding target upon ion bombardment.

When depositing a multilayer film on the substrate, the target is selected in accordance with the type of the film to be deposited. The selected target is sputtered based on the electric discharge operation caused by the power supplied to the electrode. The target material ejecting from the target forms sputtering particles to deposit on the substrate.

According to one sputtering apparatus, the ceiling portion or the like in one vacuum chamber is provided with a plurality of targets made of different target materials. At least one target is selected and sputtered to form a multilayer film on the substrate. In this sputtering apparatus, contamination among the targets caused by the sputtering particles poses a problem. More specifically, when one of the plurality of targets made of different target materials is sputtered, sputtering particles scattering from this target reach the surface of another adjacent target and are attached to it, thus contaminating it.

Conventionally, each target is provided with a shutter mechanism to interfere with the movement of the sputtering particles, thereby avoiding contamination described above on the target surface. An example for this will be described with reference to Japanese Utility Model Laid-Open No. 57-87061 and Japanese Patent Laid-Open No. 58-210166.

Japanese Utility Model Laid-Open No. 57-87061 discloses in its FIG. 3 a shutter mechanism which is provided to a sputtering apparatus to cover a target. This shutter mechanism comprises a stationary shutter mechanism portion (stationary portion) and moving shutter mechanism portion (movable portion). The stationary portion and movable portion have portions that overlap each other through a gap when the shutter is closed.

Japanese Patent Laid-Open No. 58-210166 discloses a structure in which a shutter plate is arranged at a position in front of the surface of a target at a predetermined distance from the target. The shutter plate shown in FIG. 1 of Japanese Patent Laid-Open No. 58-210166 has a plate-like shape and is arranged parallel to the plate-like target at a gap of 25 mm to 30 mm. This arrangement has a problem in that the sputtered target material leaks from the gap to outside beyond the shutter plate having the plate-like shape. To prevent this, a shutter plate shown in FIG. 2 or 3 of Japanese Patent Laid-Open No. 58-210166 is proposed. This shutter plate has a ring-like cover on the periphery of its plate-like portion. This prevents the target material from leaking to outside. According to the arrangement of FIG. 2, the cover of the shutter plate has, at a position corresponding to the outside of an anode arranged around the target, a portion that overlaps the anode electrode at a gap. According to the arrangement of FIG. 3, the distal end edge of the cover of the shutter plate comes into tight contact with an adapter arranged around the anode electrode. Each of the shutter plates shown in FIGS. 2 and 3 can be rotated and vertically moved by an arm and rotary shaft.

In the shutter mechanism described in Japanese Utility Model Laid-Open No. 57-87061, the stationary portion and movable portion of the shutter mechanism have portions that overlap each other through a gap. In the shutter structure shown in FIG. 2 of Japanese Patent Laid-Open No. 58-210166, the cover of the shutter plate has a portion that overlaps the anode electrode through a gap.

However, any of the shutter mechanisms of the above references cannot prevent inflow or outflow of sputtering particles of the target arranged in a vacuum chamber which processes the substrate.

### SUMMARY OF THE INVENTION

The present invention has been made in view of the above problem, and has as its object to provide a sputtering apparatus having a shutter mechanism which can sufficiently prevent inflow or outflow of sputtering particles of a target arranged in a vacuum chamber which processes a substrate in the vacuum chamber.

According to one aspect of the present invention, there is provided a sputtering apparatus to form a film on a substrate, comprising:

an electrode, in a vacuum chamber, having a placing surface to place a target thereon;

a stationary portion provided on a peripheral portion of the placing surface;

a shutter mechanism to shield in the vacuum chamber the target placed on the placing surface; and

a moving mechanism which sets in the vacuum chamber the shutter mechanism at a predetermined position;

wherein of the stationary portion and a movable portion of the shutter mechanism, one is provided with a recess and the other one is provided with a projection, and

when the moving mechanism sets the shutter mechanism at a position close to the stationary portion, the projection is inserted in the recess.

According to another aspect of the present invention, there is provided a sputtering apparatus which forms a plurality of types of films on a substrate, comprising:

a first electrode and a second electrode, in a vacuum chamber, respectively having placing surfaces to place different types of targets thereon;

a first stationary portion and a second stationary portion provided on peripheral portions of the placing surfaces of the first electrode and the second electrode, respectively;

a first shutter mechanism and a second shutter mechanism to shield in the vacuum chamber the targets placed on the placing surfaces of the first electrode and the second electrode; and

a first moving mechanism and a second moving mechanism which set in the vacuum chamber the first shutter mechanism and the second shutter mechanisms at predetermined positions;

wherein of the first stationary portion and a movable portion of the first shutter mechanism, one is provided with a recess and the other one is provided with a projection,

of the second stationary portion and a movable portion of the second shutter mechanism, one is provided with a recess and the other one is provided with a projection,

when the first moving mechanism sets the first shutter mechanism at a position close to the first stationary portion, the projection is inserted in the recess, and

when the second moving mechanism sets the second shutter mechanism at a position close to the second stationary portion, the projection is inserted in the recess.

One aspect of the present invention can prevent sputtering particles of a target from flowing out and being attached to a substrate during presputtering.

Another aspect of the present invention can prevent mutual contamination among a plurality of targets.

Further features of the present invention will become apparent from the following description of exemplary embodiments with reference to the attached drawings.

### BRIEF DESCRIPTION OF THE DRAWINGS

FIG. 1 is a plan view of a sputtering apparatus having vacuum chambers comprising a plurality of targets to which shutter devices are applied;

FIG. 2 is a perspective view showing the moving state of shutter movable portions in shutter mechanisms for a sputtering apparatus according to an embodiment of the present invention;

FIG. 3 is a partially sectional side view of the arrangements of the main parts of shutter devices of this embodiment; and

FIGS. 4A to 4C are respectively enlarged views of the characteristic structures of the shutter devices of this embodiment.

### DESCRIPTION OF THE EMBODIMENT

A preferred embodiment of the present invention will be described below with reference to the accompanying drawings.

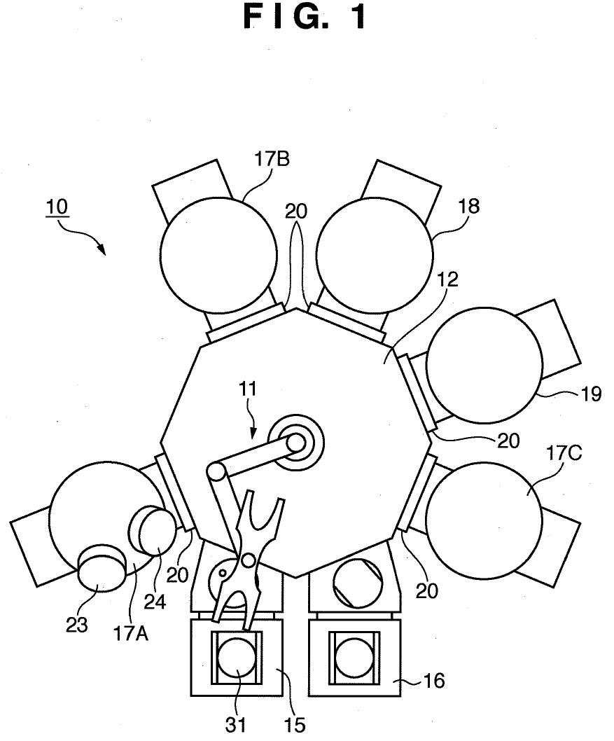

A sputtering apparatus according to this embodiment will be described with reference to FIG. 1. For example, this sputtering apparatus is an apparatus that fabricates an optical multilayer film interference filter. Note that the sputtering apparatus is not limited to an apparatus having this arrangement. FIG. 1 shows the schematic arrangement of the internal mechanism of the sputtering apparatus. In the following description, an “apparatus for fabricating an optical multilayer film interference film” will also be referred to as an “optical multilayer film fabricating sputtering apparatus” (or merely a “sputtering apparatus”). This optical multilayer film fabricating sputtering apparatus 10 has a cluster type arrangement and comprises a plurality of vacuum chambers. Some vacuum chambers among the plurality of vacuum chambers are film forming vacuum chambers, a multilayer film is formed by sputtering on one substrate mounted on a substrate holder. DC sputtering or high frequency sputtering (radio frequency sputtering) is available as the electrical discharge method. The electric discharge method is preferably the reactive DC sputtering method.

A transport chamber 12 including a robot transport device 11 is set at the central position of the optical multilayer film fabricating sputtering apparatus 10 shown in FIG. 1.

The transport chamber 12 of the optical multilayer film fabricating sputtering apparatus 10 is provided with loading/unloading chambers 15 and 16. A substrate 31 as a processing target is loaded into the loading/unloading chamber 15 of the optical multilayer film fabricating sputtering apparatus 10 from outside. The substrate 31 on which an optical multilayer film interference filter film has been formed is unloaded to outside from the loading/unloading chamber 15. The loading/unloading chamber 16 also has the same function. A substrate loaded through the loading/unloading chamber 16 is unloaded from the loading/unloading chamber 16 after an optical multilayer film interference filter film is formed on it. The two loading/unloading chambers are provided in order to improve the productivity by alternately using them.

The optical multilayer film fabricating sputtering apparatus 10 is provided with three film forming vacuum chambers 17A, 17B, and 17C, one oxide film forming vacuum chamber 18, and one cleaning vacuum chamber 19 around the transport chamber 12. Between the respective vacuum chambers 17A, 17B, 17C, 18, and 19 and the transport chamber 12, openable gate valves 20 are provided to isolate the corresponding vacuum chambers from the transport chamber 12 and to connect them to the transport chamber 12 where necessary. A vacuum evacuation mechanism, a source gas (or process gas) introducing mechanism, a power supply mechanism, and the like are added to each vacuum chamber and are not illustrated in FIG. 1. The number of film forming vacuum chambers can be changed arbitrarily in accordance with the purpose.

According to this embodiment, when forming an optical multilayer film to be deposited on a substrate, for example, the three film forming vacuum chambers 17A, 17B, and 17C are prepared, and each film forming vacuum chamber is provided with a plurality of targets. Processes (film thickness and total film number) are changed among the respective film forming vacuum chambers so that optical filter films having different wavelengths can be fabricated.

As described above, the three film forming vacuum chambers 17A, 17B, and 17C are connected by a cluster type structure to constitute the optical multilayer film fabricating sputtering apparatus 10, thus improving the productivity of the optical multilayer film interference filter.

In each of the film forming vacuum chambers 17A, 17B, and 17C, a film forming process of alternately depositing two types of dielectric films is performed using targets made of two types of film forming materials (dielectric film materials) based on, for example, the reactive DC sputtering method.

In the film forming vacuum chamber 17A, a tantalum pentoxide dielectric film and a silicon dioxide dielectric film are alternately, consecutively deposited. For this purpose, two targets 23 and 24 respectively corresponding to Ta (tantalum) and Si (silicon) are attached to the ceiling portion of the film forming vacuum chamber 17A.

In FIG. 1, the vacuum evacuation mechanism to evacuate the interior of the film forming vacuum chamber 17A to a required vacuum degree, the mechanism to supply power necessary for sputtering the targets 23 and 24, the mechanism to generate a plasma, and the like are not illustrated. This also applies to the other film forming vacuum chambers 17B and 17C.

The types and number of targets are not limited to those of the above embodiment but can be changed arbitrarily in accordance with the purpose.

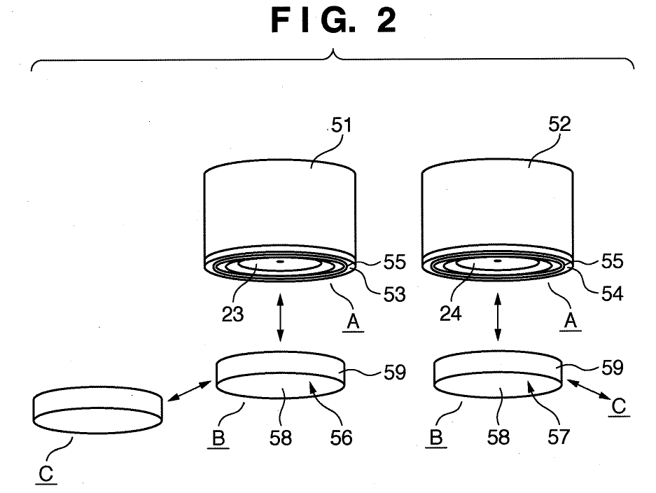

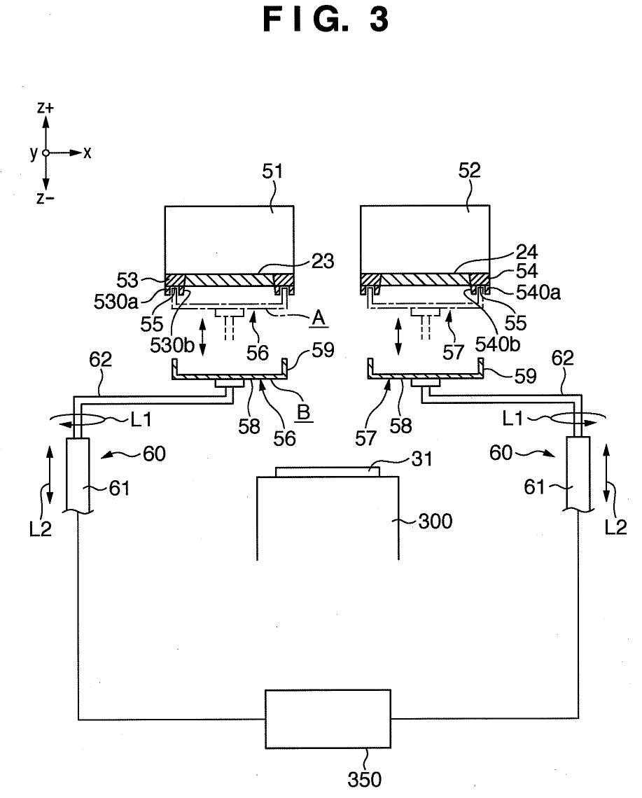

The shutter mechanisms of the optical multilayer film fabricating sputtering apparatus 10 will be described hereinafter with reference to FIGS. 2 and 3. FIG. 2 is a perspective view showing the moving state of the movable portions of the shutter mechanisms and shows the two targets 23 and 24 arranged in the film forming vacuum chamber 17A shown in FIG. 1, cathodes 51 and 52 related to the targets 23 and 24, and the main parts of the shutter mechanisms. FIG. 3 is a partially sectional side view of the arrangements of the main parts of the shutter mechanisms and shows the arrangements of the main parts of the respective shutter mechanisms.

The targets 23 and 24 are attached to the lower surfaces of the corresponding cathodes 51 and 52. The targets 23 and 24 attached to the lower surfaces of the cathodes 51 and 52 have disk-like shapes. As described above, the two targets 23 and 24 are made of different materials in accordance with the film forming substances. Furthermore, on the lower surfaces of the cathodes 51 and 52, ring-like stationary portions 53 and 54 are respectively attached at positions around the targets 23 and 24 to surround them. On the lower surface of each of the ring-like stationary portions 53 and 54, a groove 55 is formed throughout its entire circumference. More specifically, the ring-like stationary portion 53 has, on its lower surface, a ring-like member 530a, a ring-like member 530b formed on the inner side of the ring-like member 530a, and the groove 55 formed between the ring-like members 530a and 530b. For example, the ring-like members 530a and 530b can be formed concentrically. In the same manner as the ring-like stationary portion 53, the ring-like stationary portion 54 has, on its lower surface, a ring-like member 540a, a ring-like member 540b, and the groove 55. The stationary portions 53 and 54 have heights (thicknesses) which are slightly larger (e.g., 30 mm±10 mm) than those of the targets 23 and 24, respectively, and accordingly serve as shield members to a certain degree.

A shutter movable portion 56 is arranged at a position below the stationary portion 53 and target 23 attached to the lower surface of the cathode 51. A shutter movable portion 57 is arranged at a position below the stationary portion 54 and target 24 attached to the lower surface of the cathode 52. Moving mechanisms 60 can move the shutter movable portions 56 and 57 each to three positions A (shutter closing), B (shutter opening), and C (shutter retreating) shown in FIG. 2.

Each moving mechanism 60 comprises a rotary shaft portion 61 and arm 62. A rotational driving device (not shown) rotates the rotary shaft portion 61 as indicated by an arrow L1, and a vertical driving device (not shown) vertically moves the rotary shaft portions 61 entirely as indicated by an arrow L2. The arms 62 are respectively fixed to the rotary shaft portions 61 and operate similarly upon operation of the corresponding rotary shaft portions 61. The shutter movable portions 56 and 57 are attached to the distal ends of the arms 62, respectively. Accordingly, the shutter movable portions 56 and 57 operate upon operations of the corresponding moving mechanisms 60.

A controller 350 serving as a control means is connected to the two moving mechanisms 60 to control positioning of the respective moving mechanisms 60. Under the control of the controller 350, in a film forming vacuum chamber, each moving mechanism 60 positions the corresponding shutter mechanism to a predetermined position (e.g., the position A, B, or C).

The rotational driving device to rotate the rotary shaft portion 61 of the moving mechanism 60 is connected to a rotation amount detector (not shown) comprising an encoder. On the basis of the rotation amount (rotation angle) information of the rotary shaft portion 61 detected by the rotation amount detector, the controller 350 controls the rotation L1 of the rotary shaft portion 61 to a predetermined position.

The vertical driving device to perform the vertical operation of moving the arm 62 of the moving mechanism upward or downward is connected to a position detector to detect the upper position or lower position. On the basis of upper or lower position information of the arm 62 detected by the position detector, the controller 350 controls the upward movement or downward movement L2 of the arm 62 to a predetermined position.

The controller 350 can control the two moving mechanisms 60 independently of each other (in a parallel manner). This can increase the throughput of the process in the film forming vacuum chamber. For example, the controller 350 controls to retreat the shutter mechanism on the target 24 side while closing the shutter mechanism on the target 23 side. Alternatively, for example, the controller 350 can also control to retreat the shutter mechanism on the target 23 side while closing the shutter mechanism on the target 24 side.

Regarding the moving positions of the shutter movable portions 56 and 57, in FIG. 2, the positions A are shutter closing positions, and the positions B are shutter opening positions. The positions C are positions where the shutter movable portions 56 and 57 are to be retreated when sputtering the respective targets.

For example, when the shutter movable portion 56 is moved to the closing position and the target 23 is presputtered, the sputtering particles can be prevented from being attached to the substrate 31 placed on a substrate holder 300. Note that “presputtering” refers to sputtering performed to remove impurities on the oxidized target surface or on the target prior to ordinary film formation.

When moving the shutter movable portion 57 to the retreat position (position C) and sputtering the target 24, the shutter movable portion 56 is moved to the closing position (position A) to prevent the sputtering particles of the target 24 from being attached to the target 23. Similarly, when moving the shutter movable portion 56 to the retreat position (position C) and sputtering the target 23, the shutter movable portion 57 is moved to the closing position (position A) to prevent the sputtering particles of the target 23 from being attached to the target 24. The shutter movable portions 56 and 57 are moved vertically between the positions A and B by the arm 62 and horizontally between the positions B and C by the rotation (turning) of the arms 62.

Each of the shutter movable portions 56 and 57 has a disk-like plate portion 58 and a peripheral ring portion 59 which is formed along the periphery of the disk-like plate portion 58 to be integral with it.

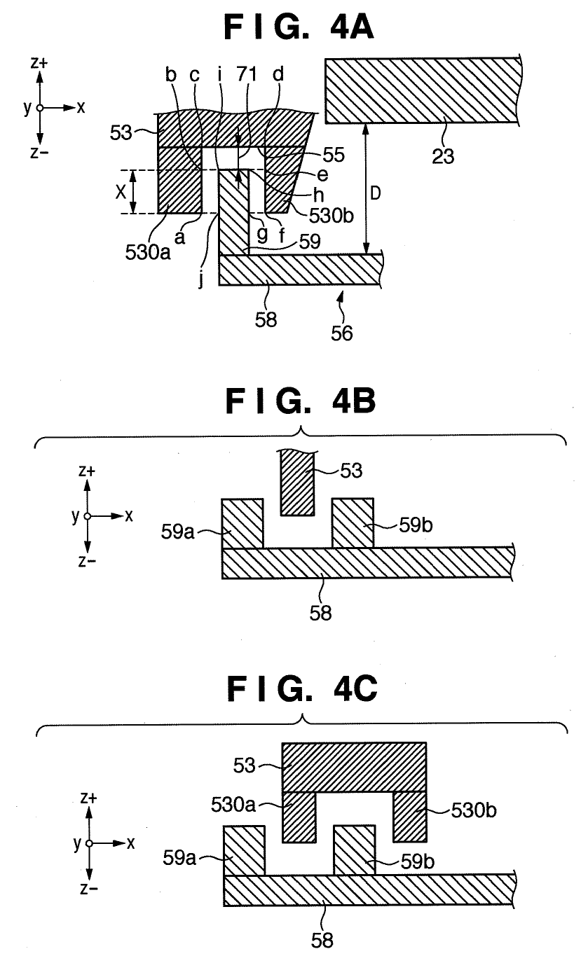

FIGS. 4A to 4C are respectively enlarged views of shutter mechanisms each according to the sputtering apparatus of the present invention.

For example, in the shutter mechanism concerning the target 23, when the shutter movable portion 56 is at the shutter closing position A to shield the target 23, that is, when the shutter mechanism is moved by the moving mechanism to a position close to the stationary portion 53, the distal end edge (projection) of the peripheral ring portion 59 of the shutter movable portion 56 is inserted in the groove 55 (recess) of the stationary portion 53. The distal end edge (projection) of the peripheral ring portion 59 of the shutter movable portion 56 is inserted in the groove 55 (recess) to be in noncontact with its side surface and bottom surface. The noncontact configuration is used for preventing particles from occurring by a contact. For example, the distal end edge (projection) of the peripheral ring portion 59 is inserted in the groove 55 to be spaced apart from the bottom surface of the groove 55 (recess) by a distance indicated by reference numeral 71. When the shutter mechanism is at the shutter closing position A, a gap (space indicated by abcdefghij in FIG. 4A) which is bent in its section is formed between the peripheral ring portion 59 of the shutter movable portion 56 and the groove 55 of the stationary portion 53, as shown in FIG. 4A. In this manner, in the positional relationship between the shutter movable portion 56 and stationary portion 53, when the shutter mechanism is in the shutter closing state (position A), the shutter movable portion 56 covers the target 23 to shield it sufficiently. Therefore, if electric discharge is generated in a space that another target 24 faces and the target 24 is to be presputtered or undergoes any other process, the shutter movable portion 56 sufficiently shields sputtering particles from the target 24 not to flow to the target 23 side, thereby preventing the target 23 from being contaminated.

When switching the shutter mechanism from the shutter closing state to the shutter opening state, the shutter movable portion 56 is moved downward from the position A to the position B by the operation of the arm 62. The peripheral ring portion 59 of the shutter movable portion 56 and the stationary portion 53 have predetermined lengths. Even if the shutter movable portion 56 is in the shutter closing state (position A), the shutter movable portion 56 and target 23 can be sufficiently separated from each other by a distance D (FIG. 4A). The distance D (FIG. 4A) is approximately 30 mm to 60 mm. Thus, a space necessary for presputtering can be ensured. As the peripheral ring portion 59 of the shutter movable portion 56 and the stationary portion 53 have the predetermined lengths, when compared to a case in which only the peripheral ring portion of the shutter movable portion 56 has a predetermined length, the movable range of the shutter movable portion 56 can be decreased. This can make the entire sputtering apparatus compact.

The distance D (FIG. 4A) is appropriately determined in accordance with the sputtering substance and sputtering conditions. The shutter movable portion 56 can be separated further away from the target 23 by rotating the rotary shaft portion 61.

As described above, when the shutter movable portion 56 of the shutter mechanism for the target 23 is at the shutter closing position A, part of the stationary portion 53 and part of the shutter movable portion 56 overlap each other to form a gap (the space indicated by abcdefghij in FIG. 4A). For example, particles traveling straight in the horizontal direction (x direction) in FIG. 4A collide against the outer peripheral portion of the ring-like member 530a or that of the peripheral ring portion 59 and cannot enter the shutter movable portion 56. Also, particles traveling straight in the vertical direction (from the z− direction to the z+ direction) in FIG. 4A collide against the cd surface of the groove 55 and cannot enter the shutter movable portion 56. The gap defined by the two ring-like members 530a and 530b provided to the stationary portion 53 and the peripheral ring portion 59 provided to the shutter movable portion 56 is formed by combination of two vertical gaps abij and ghef and a horizontal gap bcde. The gaps abij, ghef, and bcde as a whole form a shape with an opening (between a and j, and between g and f) which is bent downward. This bent gap shape makes it possible to sufficiently prevent the particles from entering the shutter movable portion 56 which is in the shutter closing state (position A).

More specifically, the gap is formed in a bent shape that when the coming particles are to pass through the gap, the particles always collide against the wall surfaces (e.g., the ac surface, cd surface, df surface, gh surface, hi surface, and ij surface) that form the gap. This can prevent the target 23 from being contaminated by the particles coming from another target 24 under sputtering. When the shutter is closed, the peripheral ring portion 59 of the shutter movable portion 56 is not in contact with the stationary portion 53. Therefore, dusting due to film separation of deposit caused by contact does not occur.

A portion X (FIG. 4A) in the shutter mechanism where the stationary portion 53 overlaps the peripheral ring portion 59 of the shutter movable portion 56 has a size of about 20 mm. The size of this overlapping portion X is changed in accordance with the substance to be sputtered, the sputtering conditions, and the like.

When the shutter mechanism for the target 23 is opened and electric discharge is caused in a space in front of the target 23 to sputter the target 23, the problem of the shadow effect that the stationary portion 53 undesirably shields the sputtering particles coming from the target 23 does not occur.

FIG. 4A explains the arrangement of the shutter movable portion 56 for the target 23. The arrangement and operation of the stationary portion 54 and shutter movable portion 57 of the shutter mechanism for the target 24 are identical to those of the shutter mechanism for the target 23 described above.

(Modifications)

FIGS. 4B and 4C are modifications of the shutter mechanism shown in FIG. 4A. As shown in FIG. 4B, the disk-like plate portion 58 of the shutter movable portion 56 may be provided with a peripheral ring portion 59a and a peripheral ring portion 59b which is formed on the inner side of the ring-like member 59a. The ring-like members 59a and 59b can be formed concentrically. The disk-like plate portion 58 of the shutter movable portion 57 may be provided with a peripheral ring portion 59a and a peripheral ring portion 59b which is formed on the inner side of the ring-like member 59a, in the same manner as in FIG. 4B.

For example, a sputtering apparatus which forms a plurality of types of films on a substrate comprises, in the vacuum chamber, the first and second electrodes 51 and 52 having placing surfaces on each of which a plurality of different types of targets are to be placed. The sputtering apparatus also comprises the first and second stationary portions 53 and 54 formed on the peripheral portions of the placing surfaces of the first and second electrodes 51 and 52, respectively. The sputtering apparatus also comprises the first and second shutter mechanisms to shield the targets 23 and 24, placed on the respective placing surfaces of the first and second electrodes 51 and 52, in the vacuum chamber. The sputtering apparatus also comprises the first and second moving mechanisms which position the first and second shutter mechanisms each at predetermined positions (e.g., a position A, B, or C) in the vacuum chamber.

Of the first stationary portion 53 and the movable portion 56 of the first shutter mechanism, for example, one is provided with a recess and the other is provided with a projection, as shown in FIGS. 3, 4A, and 4B.

Of the second stationary portion 54 and the movable portion 57 of the second shutter mechanism, for example, one is provided with a recess and the other is provided with a projection, as shown in FIGS. 3, 4A, and 4B.

When the first moving mechanism 60 sets the first shutter mechanism at a position close to the first stationary portion 53, the projection is inserted in the recess. When the second moving mechanism 60 sets the second shutter mechanism at a position close to the second stationary portion 54, the projection is inserted in the recess.

Furthermore, as shown in FIG. 4C, the stationary portion 53 may be provided with two ring-like members 530a and 530b, and the shutter movable portion 56 may be provided with two ring-like portions 59a and 59b formed on the disk-like plate portion 58. In this case, the two ring-like members 530a and 530b can be formed concentrically. The two ring-like portions 59a and 59b can be formed concentrically.

In the same manner as in FIG. 4C, the stationary portion 54 may be provided with two ring-like members 530a and 530b, and the shutter movable portion 57 may be provided with two ring-like members 59a and 59b formed on the disk-like plate portion 58.

Note that the arrangements, shapes, and positional relationships described in the above embodiment are merely examples explained schematically to such a degree that the present invention can be understood. Also, the numerical values and the compositions (materials) of the respective arrangements are merely examples. Accordingly, the present invention is not limited to the specific embodiment described above, and can be changed in various manners as long as it does not depart from the scope of the technical idea presented in the claims.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2007-337370, filed Dec. 27, 2007, which is hereby incorporated by reference herein in its entirety.

What is claimed is:

1. A sputtering apparatus to form a film on a substrate, comprising:
an electrode, in a vacuum chamber, having a placing surface to place a target thereon;
a stationary portion provided on a peripheral portion of the placing surface;
a shutter mechanism to shield in the vacuum chamber the target placed on the placing surface; and
a moving mechanism which sets in the vacuum chamber said shutter mechanism at a predetermined position;
wherein of said stationary portion and a movable portion of said shutter mechanism, one is provided with a recess and the other one is provided with a projection, and
when said moving mechanism sets said shutter mechanism at a position close to said stationary portion, the projection is inserted in the recess.

2. The apparatus according to claim 1, wherein the recess includes at least two concentric ring-like members and a groove formed between the two ring-like members.

3. The apparatus according to claim 1, wherein the projection comprises a ring-like member.

4. The apparatus according to claim 1, wherein the projection is inserted in the recess to be in noncontact therewith.

5. The apparatus according to claim 1, further comprising control means for controlling positioning of said moving mechanism.

6. A sputtering apparatus which forms a plurality of types of films on a substrate, comprising:
a first electrode and a second electrode, in a vacuum chamber, respectively having placing surfaces to place different types of targets thereon;
a first stationary portion and a second stationary portion provided on peripheral portions of the placing surfaces of said first electrode and said second electrode, respectively;
a first shutter mechanism and a second shutter mechanism to shield in the vacuum chamber the targets placed on the placing surfaces of said first electrode and said second electrode; and
a first moving mechanism and a second moving mechanism which set in said vacuum chamber said first shutter mechanism and said second shutter mechanisms at predetermined positions;
wherein of said first stationary portion and a movable portion of said first shutter mechanism, one is provided with a recess and the other one is provided with a projection,
of said second stationary portion and a movable portion of said second shutter mechanism, one is provided with a recess and the other one is provided with a projection,
when said first moving mechanism sets said first shutter mechanism at a position close to said first stationary portion, the projection is inserted in the recess, and
when said second moving mechanism sets said second shutter mechanism at a position close to said second stationary portion, the projection is inserted in the recess.

7. The apparatus according to claim 6, wherein the recess includes at least two concentric ring-like members and a groove formed between the two ring-like members.

8. The apparatus according to claim 6, wherein the projection comprises a ring-like member.

9. The apparatus according to claim 6, wherein the projection is inserted in the recess to be in noncontact therewith.

10. The apparatus according to claim 6, further comprising control means for controlling positioning of said first moving mechanism and said second moving mechanism.
